(19) United States
(12) Patent Application Publication
(10) Pub. No.: US 2014/0150865 A1
(43) Pub. Date: Jun. 5, 2014

(54) CONCENTRATING SOLAR CELL

(71) Applicants: Jin Hyuk Kwon, Daegu (KR); Jae Hak Jung, Daegu (KR)

(72) Inventors: Jin Hyuk Kwon, Daegu (KR); Jae Hak Jung, Daegu (KR)

(73) Assignee: Industry-Academic Cooperation Foundation, Yeungnam University, Gyeongsangbuk-do (KR)

(21) Appl. No.: 14/129,570

(22) PCT Filed: Jun. 26, 2012
(86) PCT No.: PCT/KR2012/005042

§ 371 Date: Feb. 7, 2014

(30) Foreign Application Priority Data
Jun. 29, 2011 (KR) 10-2011-0063317

(51) Int. Cl. H01L 31/052

(52) U.S. Cl. CPC H01L 31/0524; H01L 31/0527
USPC 136/259

(57) ABSTRACT

The present invention relates to a solar cell capable of maximizing a concentrating area and cell efficiency by disposing a cell in a progress direction of light, that is, in a vertical direction to a concentrating direction.

### TECHNICAL FIELD

The present invention relates to a solar cell.

A solar cell is an apparatus which directly converts light energy into electric energy by using a photo voltaic effect and produces electricity by using a potential difference generated between a P pole and an N pole by a transfer of charges generated when light is irradiated to a junction of P type semiconductor and N type semiconductor. Describing in more detail, when light is irradiated to the solar cell, electrons and holes are generated inside the solar cell. The so generated charges move to P and N poles, such that a potential difference (photoelectron-motive force) may be generated between the P and N poles. In this case, when loads are connected to the solar cell, a current flows, such that electricity may be produced. Generally, among the solar cells, a silicon solar cell which is manufactured to include an N type silicon semiconductor layer formed by diffusing phosphor on the P type semiconductor in which boron is added to silicon is inexpensive and easily mass-produced, and thus has been mainly used.

With the development of industries, fossil energy resources are depleted and environmental pollution problems are on the rise currently. Therefore, the development of eco-friendly energy which may substitute the existing fossil energy is urgently required. The solar cell-related technologies have been researched and developed long since to serve as alternative energy. In the solar cell as described above, solar cell efficiency largely depends on materials. The materials used in the solar cell are very expensive, and thus may seldom be commercialized.

Therefore, among the research fields of the solar cell, research into a method of further increasing solar cell efficiency than in the case of using the same material has been very actively conducted. One of the research fields relates to a system which amplifies a light source and increases power generation efficiency by concentrating sunlight on a high-efficiency solar cell, such as GaAs, through a lens or a reflector, as concentrating photo voltaic (CPV), that is, a concentrating solar system. The method reduces an area of the solar cell to obtain targeted power and largely reduces the area of the expensive high-efficiency solar cell, such that the CPV reduces manufacturing costs of the expensive cell, thereby reducing power production costs. It is proven that it is possible to achieve considerable cost saving and relatively easily obtain energy efficiency by about 50% using only the CPV technology, have been presently conducted. Therefore, research and utilization for the CPV technology are expected to be more actively conducted.

### BACKGROUND ART

FIG. 1 illustrates several exemplary embodiments of solar cells according to the related art.

FIG. 1(A) illustrates a structure of a solar cell used in the above-mentioned CPV system, and the like, which is a design disclosed in US Patent Laid-Open Publication No. 2010/0032005 entitled “System and Method for Solar Energy Capture” (hereinafter, Related Art 1). As described above, the concentrating solar system concentrates sunlight by using a convex lens, a Fresnel lens, a reflector, and the like which may concentrate light and concentrates the collected sunlight on the cell, such that targeted power may be obtained by only a cell having a narrower area. Related Art 1 illustrated in FIG. 1(A) also discloses a structure for more efficiently concentrating sunlight. However, in the case of the Related Art 1, it is essential to install a structure for fixing the concentrating parts (lens, reflector, and the like) in a proper place and there is a problem in that a volume, a weight, and the like of the solar cell are increased due to limitations such as a large volume of the concentrating parts and an interval between the concentrating parts for concentrating light and the cell which corresponds to approximately a focal distance.

FIG. 1(B) illustrates a design disclosed in Korean Patent Laid-Open Publication No. 2010-0081257 entitled “Solar Cell Structure With Optical Cavity Constructed Via Full-Reflective Layer AT The Bottom And Semi-Reflective Layer At The Top, And The Fabrication Method As Same” (hereinafter, Related Art 2). In more detail, Related Art 2 discloses a solar cell unit cell including: a concave bottom contact; a conductive reflective layer which is formed on the concave bottom contact; a transparent electrode which is stacked over a lower concave bottom contact; a light absorption layer which is formed in a focal region over the transparent electrode; an anti-reflective layer which has one-way transmittance with respect to incident light formed over the light absorption layer; and an upper electrode connected to the conductive anti-reflective layer. As illustrated in FIG. 1(B), the Related Art 2 may more reduce a volume than the Related Art 1, but since the Related Art 2 also includes the concave mirror disposed under the cell, the increase in the volume as much as the concave mirror may not be avoided.

Above all, since the existing concentrating structure as well as the above-mentioned Related Arts has a structure in which the concentrating parts (lens, reflector, and the like) and the cell are disposed in parallel with a progress direction of light, the number of cells which may be disposed on the same area (due to the limitation in the volume as described above) may also be limited, such that the increase in concentrating efficiency may also be limited.

### DISCLOSURE

### Technical Problem

Therefore, the present invention has been made in an effort to provide an inexpensive high-efficiency solar cell panel, in which a cell is vertically disposed to a progress direction of light, that is, a concentrating direction, a micro lens array is used as a concentrating instrument to make a thickness of a solar panel very thin, a concentrating solar panel or an optical fiber array is installed at a focal position of the micro lens array to increase a density of light, thereby minimizing a concentrating area of a solar cell.

### Means for Solving the Problem

In order to achieve the above objects, the present invention provides a concentrating solar cell, including: when a progress direction of sunlight, that is, a direction in which sunlight is progressed along a concentrating direction is defined as a lower portion and an opposite direction thereto is defined as an upper portion, a concentrating unit 110 which has a plate shape in which a plurality of concentrating devices 111 concentrating sunlight are disposed in an array form or a matrix form; a light induction unit 120 which is disposed under the concentrating unit 110 and converts a direction of sunlight collected to the concentrating unit 110 into a vertical direction to the concentrating direction; and a power generation unit 130 which is disposed on one side of the light induction unit 120 and is formed of a solar cell array to receive the sunlight converted and input by the light induction unit 120 so as to produce power.

The light induction unit 120 may be configured to include a plate made of a transparent material into which light is transmitted or an optical fiber.

The light induction unit 120A may have a plate 121A shape made of a transparent material into which light is transmitted and may be provided a plurality of reflective units 125A which reflects sunlight concentrated at positions corresponding to positions of each of the concentrating devices 111 and converts a direction of the sunlight, in which the reflective unit 125A may be configured to include a groove 122A having a form depressed on the plate 121A and an reflective layer 123A on the whole surface of the groove 122A.

A light induction unit 120B may be configured to include a plurality of light induction paths 121B which are formed of an optical fiber, and one cross section of the light induction unit 120B may be disposed at the positions corresponding to the positions of each of the concentrating devices 111 and the other cross section thereof may be disposed at the positions of each of the solar cells forming the power generation unit 130, such that the sunlight incident to the one cross section is transmitted to the other cross section and is incident to the power generation unit 130.

A light induction unit 120C may be configured to include a plurality of reflective light induction paths 121C which are formed of an optical fiber, and one end of the reflective light induction unit 120C may be disposed at positions corresponding to the positions of each of the concentrating devices 111 and the other cross section thereof may be disposed at the positions of each of the solar cells forming the power generation unit 130, the one end thereof may have an inclined cross section to an extending direction of the optical fiber, and the inclined cross section of the one end may be provided with a reflective layer 122C to reflect the sunlight incident to the one end by the reflective layer 122C of the inclined cross section and transmit the reflected sunlight to the other cross section to be incident to the power generation unit 130.

The concentrating device 111 may be a micro lens formed in a convex lens form and a Fresnel lens form.

The solar cell 100 may be any one selected from high-efficiency solar cells including a high-efficiency crystalline Si solar cell, a tandem cell including a form in which Ge, GaAs, and GaInP are stacked, a GaAs solar cell, a CIGS-based thin film solar cell, an a-Si thin film solar cell, and a CdTe thin film solar cell.

### Advantageous Effects

According to the exemplary embodiments of the present invention, it is possible to fundamentally remove the problem in that the increase in the cell efficiency is limited since in the concentrating solar cell structure according to the related art, the concentrating parts, such as a lens and a reflector, are large and heavy and the concentrating parts and the solar cell are disposed in parallel with the progress direction of light to limit the number of cells which may be disposed per the concentrating area, make the thickness thin and light by using the integrated type micro optical lens and light induction path, and more remarkably increase the concentrating efficiency as well as the solar cell efficiency from the high-intensity light incident from the plurality of concentrating lenses by disposing the high-efficiency small solar cell on one side or both sides of the light induction path than the related art.

Further, according to the exemplary embodiments of the present invention, since the cell itself is much more expensive than the optical parts for concentrating light and the size of the solar cell does not greatly affect the increase in cost even though the concentrating area is increased, the concentrating area of the micro optical lens in which the plurality of condensers are included may be much more increased than the related art even when the size of the solar cell is fixed, thereby more saving the power production cost than the related art.

### BRIEF DESCRIPTION OF THE DRAWINGS

FIG. 1 is a diagram illustrating several exemplary embodiments of a solar cell according to the related art.

FIG. 2 is a concentrating solar cell according to an exemplary embodiment of the present invention.

FIG. 3 is a diagram illustrating a concentrating solar cell according to a first exemplary embodiment of the present invention.

FIG. 4 is a diagram illustrating a concentrating solar cell according to a second exemplary embodiment of the present invention.

FIG. 5 is a diagram illustrating a concentrating solar cell according to a third exemplary embodiment of the present invention.

FIGS. 6 and 7 are top views of the concentrating solar cell according to the exemplary embodiment of the present invention.

### DETAILED DESCRIPTION OF MAIN ELEMENTS

100: (The present inventive) Solar cell
110: Concentrating unit
111: Concentrating device
120: Light induction unit
120A: Light induction unit according to first exemplary embodiment
121A: Plate
122A: Groove
123A: Reflective layer
125A: Reflective unit
120B: Light induction unit according to second exemplary embodiment
121B: Light induction path
120C: Light induction unit according to third exemplary embodiment
121C: Reflective light induction path
122C: Reflective layer
130: Power generation unit

### BEST MODE

Hereinafter, a concentrating solar cell according to exemplary embodiments of the present invention having the above configuration will be described in detail with reference to the accompanying drawings.

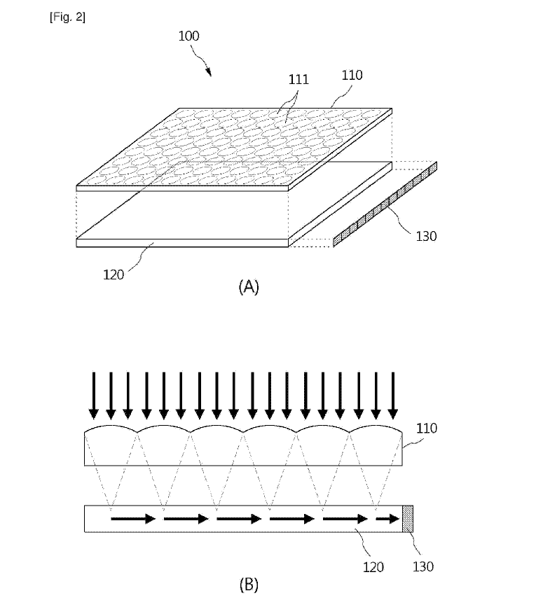

FIG. 2 schematically illustrates a structure of a concentrating solar cell according to an exemplary embodiment of the present invention. As illustrated in FIG. 2, a solar cell 100 according to the exemplary embodiment of the present invention includes a concentrating unit 110, a light induction unit 120, and a power generation unit 130, in which the concentrating unit 110 and the power generation units 130 are similar to components configuring the solar cell according to the related art, but converts a direction of sunlight concentrated through the concentrating unit 110 by using the light induction unit 120 and makes the sunlight be incident to the power generation unit 130. Hereinafter, each component will be described in more detail. For reference, in the following description, a progress direction of sunlight, that is, a direction in which sunlight is progressed along a concentrating direction is defined as a lower portion and an opposite direction thereto is defined as an upper portion. The reason is that an angle of sunlight with respect to a ground is continuously changed depending on date, time, and the like, but a solar cell is configured to rotate at an angle (that is, an angle at which the sunlight is vertically incident to a surface of the solar cell) at which the sunlight may be best received. Further, even though the sunlight is not vertical with respect to the surface of the solar cell, in the solar cell, an approximately vertical direction depending on the progress direction of sunlight is always determined distinctly, and thus a direction in which the sunlight is progressed may be called the lower portion without any major trouble.

The concentrating unit 110 is configured to have a plate shape in which a plurality of concentrating devices 111 concentrating sunlight are disposed in an array form or a matrix form. Herein, the concentrating device 111 may be a micro lens in a convex lens form or a Fresnel lens form. That is, the concentrating unit 110 has a plate shape in which the plurality of micro lenses are disposed vertically and horizontally. Further, if the concentrating unit 110 has a shape in which as in the case when all the concentrating devices 111 may be separately made as independent component and then made to be coupled on any frame, all the concentrating units 110 may be made in an integrated type from the beginning to have the above shape, or the like, the concentrating devices 111, such as a micro lens, are vertically and horizontally disposed in a plurality of array or matrix forms, the detailed form of the concentrating unit 110 may be variously changed depending on a designer's intention, purpose, and the like.

As described above, the light induction unit 120 is a feature portion of the solar cell 100 according to the exemplary embodiment of the present invention and is disposed under the concentrating unit 110 and serves to convert a direction of sunlight collected to the concentrating unit 110 into a direction vertical with respect to the concentrating direction. To convert the direction of sunlight, a mirror, a prism, or the like which is optical components used to convert a direction of light may be generally used and the light induction unit 120 according to the exemplary embodiment of the present invention may also be made by applications of the optical components. Further, according to the exemplary embodiment of the present invention, the light induction unit 120 may be configured to include a plate made of a transparent material into which light may be transmitted or an optical fiber, in addition to a mirror, a prism, and the like as described above. A principle of converting a direction of light using the plate or the optical fiber will be described in more detail with reference to the detailed exemplary embodiments.

The power generation unit 130 is disposed on one side of the light induction unit 120 and is formed of solar cell arrays and receives sunlight converted by the light induction unit 120 to produce power. According to the solar cell according to the related art, the power generation unit 130 is disposed under the concentrating unit 110 and is configured to make the sunlight concentrated by the concentrating unit 110 be incident to the power generation unit 130 as it is. However, according to the exemplary embodiment of the present invention, the concentrated sunlight is once converted by the light induction unit 120 and the power generation unit 130 is disposed on one side of the light induction unit 120.

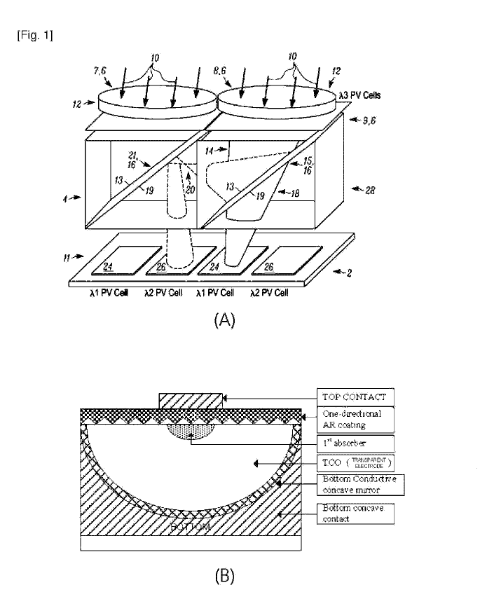

By doing so, a gain obtained by the solar cell 100 according to the exemplary embodiment of the present invention will be described in more detail. In the solar cell according to the related art as illustrated in FIG. 1, the concentrated sunlight is incident to the solar cell as it is. Therefore, one cell per a unit concentration device is disposed, such that when there is a plate in which the concentrating devices are disposed, the plate in which cells are disposed cannot also help occupying substantially the same area. In this case, in the plate in which the cells are disposed, the remaining area other than a portion at which light is collected by the concentration may be considerably generated. However, in the solar cell according to the related art, methods of reducing or using the remaining area in terms of the structure of the solar cell are not present and a volume of the solar cell may not be reduced to some range or less.

However, in the solar cell 100 according to the exemplary embodiment of the present invention, the direction of concentrated sunlight is converted by the light induction unit 120 and the cell is disposed at a side at which the direction of sunlight is converted. As illustrated in FIG. 2 (having an array form in which cells are gathered), the power generation unit 130 may be disposed on a side of the light induction unit 120 having the plate shape, that is, on a very narrow area. That is, in the solar cell according to the related art, since light does not reach an inter-cell, an extra area is generated unavoidably, but in the solar cell 100 according to the exemplary embodiment of the present invention, the extra area is never required and the cells may be integrated at a much higher level. Further, since the sunlight concentrated by the plurality of concentrating devices 111 is collectively progressed in one direction by the light induction unit 120, the additional concentrating effect is further produced, and thus the concentrating efficiency is more increased.

Therefore, to reach the same targeted power by using the same number of cells, the area of the concentrating unit 110 may be more reduced when the solar cell according to the exemplary embodiment of the present invention is used, whereas the same targeted power may be reached by using a smaller number of cells for the area of the same concentrating unit (since the concentrating efficiency is increase). As generally well known, in connection with manufacturing cost of the solar cell, the optical components, and the like are much cheaper than the cell. That is, it may be considered that the solar cell cost depends on the cell cost. In this case, according to the exemplary embodiment of the present invention, the concentrating efficiency may be more increased by extending the area of the concentrating unit 110 while using the same number of cells, such that an economic effect to more reduce power production cost in contradiction to possible production power may be obtained.

Further, according to the related art, to prevent the cell from being disposed at a position out of the concentrated position, the positioning problem of the cell is an important consideration during the manufacturing process, but according to the exemplary embodiment of the present invention, since the sunlight is collectively progressed from the light induction unit 120 toward the one direction, the positioning of the cell becomes relatively more free. That is, according to the exemplary embodiment of the present invention, the difficulty in the manufacturing process of the solar cell 100 may be more reduced, which may additionally reduce the production cost. Further, although describing in more detail the following exemplary embodiments, in the solar cell 100 according to the exemplary embodiment of the present invention, since the light induction unit 120 has a very simple configuration and does not have factors to increase the volume, the volume of the solar cell may be more reduced than the related art.

In addition, the solar cell 100 may be any one selected from high-efficiency solar cells including a high-efficiency crystalline Si solar cell, a tandem cell including a form in which Ge, GaAs, and GaInP are stacked, a GaAs solar cell, a CIGS-based thin film solar cell, an a-Si thin film solar cell, and a CdTe thin film solar cell.

Hereinafter, the solar cell 100 according to several exemplary embodiments of the present invention, in particular, several exemplary embodiments of the detailed configuration of the light induction unit 120 will be described in more detail.

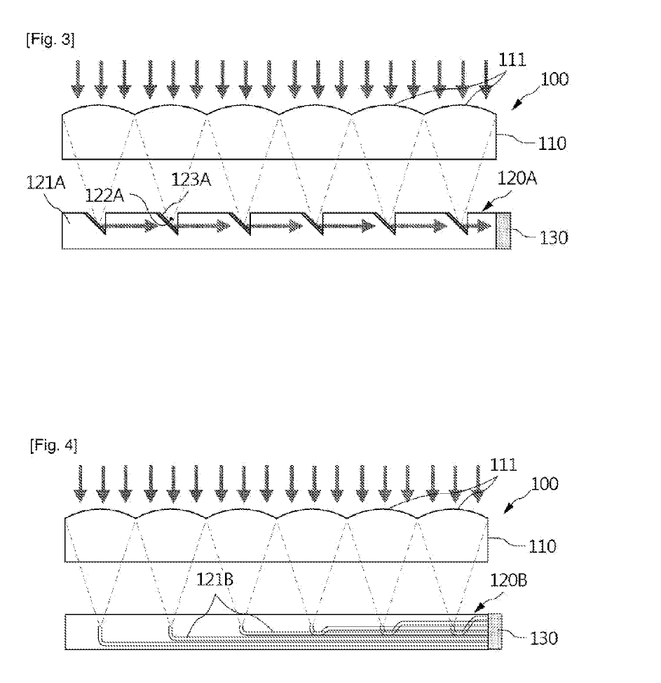

According to a first exemplary embodiment of the present invention illustrated in FIG. 3, a light induction unit 120A basically has a plate 121A shape made of a transparent material into which light may be transmitted. In this case, a plurality of reflective units 125A which reflects sunlight concentrated at positions corresponding to the positions of each of the concentrating devices 111 and converts the direction of sunlight are disposed on the plate 121A. Describing in more detail the shape of the reflective unit 125A, the reflective unit 125A is configured to include a groove 122A which has a shape depressed on the plate 121A and a reflective layer 123A formed on the whole surface of the groove 122A. That is, the reflective layer 123A coated on the groove 122A serves as a mirror, such that the concentrated sunlight is progressed while being directed to the power generation unit 130.

According to a second exemplary embodiment of the present invention illustrated in FIG. 4, a light induction unit 120B is configured to include a plurality of light induction paths 121B formed of an optical fiber. Light incident to one end of the optical fiber is progressed along an extending direction of the optical fiber inside the optical fiber (independent of how the optical fiber is bent), such that light comes out from the other end of the optical fiber. By using the characteristics of the optical fiber, the second exemplary embodiment of the present invention uses the optical fiber to transmit the concentrated sunlight to the power generation unit 130. Describing in more detail, one cross section of the light induction path 121B is disposed at the positions corresponding to the positions of each of the concentrating devices 111 and the other cross section thereof is disposed at the positions of each of the solar cells forming the power generation unit 130, such that the sunlight incident to the one cross section is transmitted to the other cross section and is incident to the power generation unit 130.

According to a third exemplary embodiment of the present invention illustrated in FIG. 5, a light induction unit 120C is also configured to include a plurality of light induction paths 121C. Even in the third exemplary embodiment similar to the second exemplary embodiment, one end of the reflective light induction path 121C is disposed at the positions corresponding to the positions of each of the concentrating devices 111 and the other cross section thereof is disposed at the positions of each of the solar cells forming the power generation unit 130. In this case, the shape of the one end is slightly different from the second exemplary embodiment of the present invention. As illustrated, in the third exemplary embodiment of the present invention, the one end has an inclined cross section with respect to the extending direction of the optical fiber and the inclined cross section of the one end is provided with a reflective layer 122C. That is, the reflective layer 122C serves as the mirror to progress the concentrated sunlight into the optical fiber, such that the sunlight incident to the one end is reflected by the reflective layer 122C having the inclined cross section and is transmitted to the other cross section and is incident to the power generation unit 130.

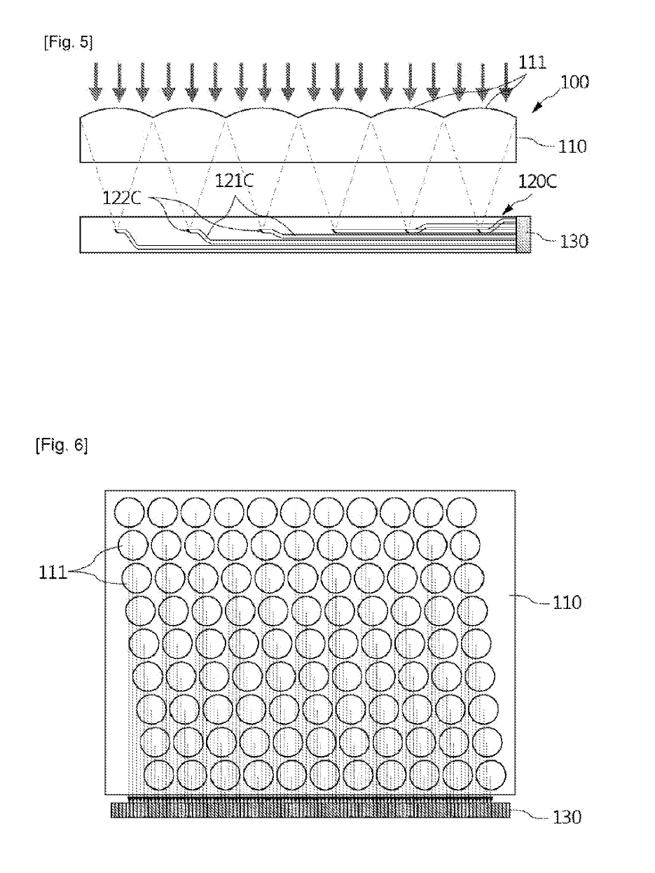

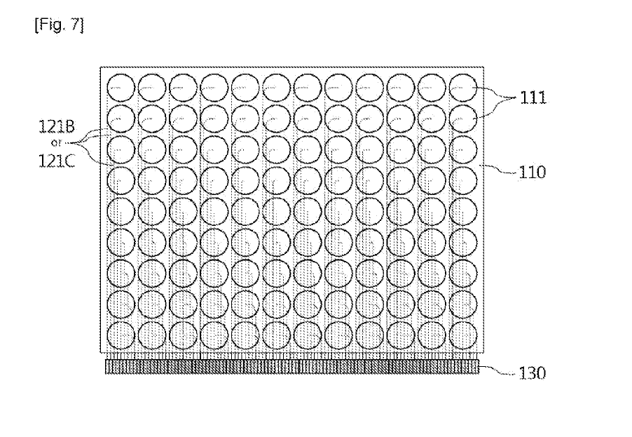

FIGS. 6 and 7 illustrate top views of the exemplary embodiments of the present invention.

In the case of the first exemplary embodiment (FIG. 3) of the present invention, as illustrated in FIG. 3, the reflective units 125A are disposed in parallel so as to be disposed at the same position (that is, the same height) in a vertical direction. In this case, the light reflected from the reflective unit 125A at the left of FIG. 3 is locked to the reflective unit 125A at the right of FIG. 3 to reduce the transmitted light quantity. To avoid this, a height of the reflective unit 125A may be appropriately controlled and disposed to prevent the paths of the light reflected from the reflective units 125A from overlapping with each other. Alternatively, the heights of the reflectors 125A are the same as illustrated in FIG. 3 and as illustrated in the top view of FIG. 6, the concentrating devices 111 are disposed to be slightly deviate from each other so as not to be parallel with each other on a plane, such that the paths of the light reflected from the reflective units 125A do not overlap each other.

The second exemplary embodiment (FIG. 4) of the present invention and the third exemplary embodiment (FIG. 5) of the present invention illustrate that the optical induction path 121B or the reflective optical induction path 121C which is formed of the optical fiber is bent so as not to overlap each other in a vertical direction, in which the optical fibers corresponding to each of the concentrating positions are separately illustrated to show optical fibers which are independent from each other, but the optical fibers may be substantially disposed in a vertical direction. FIG. 7 illustrates a top view of one example of the disposition form of the optical fiber. As described above, even though the optical fiber is bent in any form, light is progressed through the inside of the optical fiber, and therefore even though the optical fiber does not have a form illustrated in FIG. 7, the disposition of the optical fiber may be variously formed depending on the designer's purpose or intention without any limitation. When the optical fiber is disposed as illustrated in FIG. 7, there is no risk that the optical fibers are disposed to overlap each other in a vertical direction. In this case, all the optical fibers may be disposed in parallel with each other in a vertical direction, that is, on the same plane. Alternatively, even in the second exemplary embodiment of the present invention and the third exemplary embodiment of the present invention, when viewed from the top, the form illustrated in FIG. 6, that is, the form in which the concentrating devices 111 are disposed to deviate from each other on the plane may be adopted.

The present invention is not limited to the above-mentioned exemplary embodiments but may be variously applied, and may be variously modified by those skilled in the art to which the present invention pertains without departing from the gist of the present invention claimed in the claims.

### INDUSTRIAL APPLICABILITY

According to the exemplary embodiments of the present invention, since the cell itself is much more expensive than the optical parts for concentrating light and the size of the solar cell does not greatly affect the increase in cost even though the concentrating area is increased, the concentrating area of the micro optical lens in which the plurality of condensers are included may be much more increased than the related art even when the size of the solar cell is fixed, thereby more saving the power production cost than the related art.

1. A concentrating solar cell, comprising:
when a progress direction of sunlight, that is, a direction in which sunlight is progressed along a concentrating direction is defined as a lower portion and an opposite direction thereto is defined as an upper portion,
a concentrating unit 110 which has a plate shape in which a plurality of concentrating devices 111 concentrating sunlight are disposed in an array form or a matrix form;
a light induction unit 120 which is disposed under the concentrating unit 110 and converts a direction of sunlight collected to the concentrating unit 110 into a vertical direction to the concentrating direction; and
a power generation unit 130 which is disposed on one side of the light induction unit 120 and is formed of a solar cell array to receive the sunlight converted and input by the light induction unit 120 so as to produce power.

2. The concentrating solar cell of claim 1, wherein the light induction unit 120 is configured to include a plate made of a transparent material into which light is transmitted or an optical fiber.

3. The concentrating solar cell of claim 1, wherein the light induction unit 120A has a plate 121A shape made of a transparent material into which light is transmitted and is provided a plurality of reflective units 125A which reflects sunlight concentrated at positions corresponding to positions of each of the concentrating devices 111 and converts a direction of the sunlight, and
the reflective unit 125A is configured to include a groove 122A having a form depressed on the plate 121A and a reflective layer 123A on the whole surface of the groove 122A.

4. The concentrating solar cell of claim 1, wherein a light induction unit 120B is configured to include a plurality of light induction paths 121B which are formed of an optical fiber, and one cross section of the light induction unit 120B is disposed at the positions corresponding to the positions of each of the concentrating devices 111 and the other cross section thereof is disposed at the positions of each of the solar cells forming the power generation unit 130, such that the sunlight incident to the one cross section is transmitted to the other cross section and is incident to the power generation unit 130.

5. The concentrating solar cell of claim 1, wherein a light induction unit 120C is configured to include a plurality of reflective light induction paths 121C which are formed of an optical fiber, and one end of the reflective light induction unit 120C is disposed at positions corresponding to the positions of each of the concentrating devices 111 and the other cross section thereof is disposed at the positions of each of the solar cells forming the power generation unit 130, the one end thereof has an inclined cross section to an extending direction of the optical fiber, and the inclined cross section of the one end is provided with a reflective layer 122C to reflect the sunlight incident to the one end by the reflective layer 122C of the inclined cross section and transmit the reflected sunlight to the other cross section to be incident to the power generation unit 130.

6. The concentrating solar cell of claim 1, wherein the concentrating device 111 is a micro lens formed in a convex lens form and a Fresnel lens form.

7. The concentrating solar cell of claim 1, wherein the solar cell 100 is any one selected from high-efficiency solar cells including a high-efficiency crystalline Si solar cell, a tandem cell including a form in which Ge, GaAs, and GaInP are stacked, a GaAs solar cell, a CIGS-based thin film solar cell, an a-Si thin film solar cell, and a CdTe thin film solar cell.
